(19) United States
(12) Patent Application Publication
(10) Pub. No.: US 2011/0004421 A1
(43) Pub. Date: Jan. 6, 2011

(54) METHOD OF INFERENCE OF APPLIANCE USAGE. DATA PROCESSING APPARATUS AND/OR COMPUTER SOFTWARE

(75) Inventors: Neil Alexander Rosewell, Cambridgeshire (GB); Hans Joachim Steiner, Cambridge (GB); Matthew Emmanuel Milton Storkey, Cambridge (GB); Edward Grellier Colby, Cambridge (GB); Adam Laurence Camilletti, Cambridge (GB); David Healey, Suffolk (GB); Joseph Moorhouse, Oxfordshire (GB)

Correspondence Address: THORPE NORTH & WESTERN, LLP., P.O. Box 1219, SANDY, UT, 84091-1219, US

(73) Assignee: SENTEC LIMITED, Cambridge (GB)

(21) Appl. No.: 12/919,005

(22) PCT Filed: Feb. 20, 2009
(86) PCT No.: PCT/GB2009/000482

§ 371 Date: Aug. 23, 2010

(30) Foreign Application Priority Data
Feb. 21, 2008 (GB) 0803140.3

(51) Int. Cl. G06F 19/00; G01R 21/00; G01F 1/00

(52) U.S. Cl. 702/45; 702/60

(57) ABSTRACT

A method of inference of appliance usage from a point measurement on a supply line, said supply line being common to multiple appliances and/or components of appliances comprises the steps of: obtaining data from said measurement point; sampling power and reactive power at intervals substantially throughout periods of operation of said appliances or components of appliances corresponding to appliances or components of appliances being in ON and/or OFF modes of use; identifying characteristics of events by assessing power and reactive power change during an event; and by assessing one or more additional characteristics derivable from said power and reactive power to characterise an appliance; grouping events and/or cycles of events into clusters of similar characteristics; and inferring appliance usage based on said grouping.

### FIELD OF THE INVENTION

The invention relates to methods of inference of appliance usage, data processing apparatuses and/or computer software.

These concern the field of electrical power usage as well as fluid usage such as gas and water.

### BACKGROUND AND PRIOR ART KNOWN TO THE APPLICANT(S)

The closest prior art identified is U.S. Pat. No. 4,858,146 (1989) since this concerns a single point appliance monitor. The analysis carried out in this prior method requires steady state power levels and assesses the difference between steady state levels to detect events. Analysis is only carried out after the signals are passed through a steady state detector (see column 4, lines 29 to 33). Indications direct the skilled man not to consider starting transients which would otherwise introduce error into the process (see column 5, lines 14 to 24). The cluster analysis is therefore deemed only to be accurate following the steady state detector. Even when multiple dimensions are suggested (column 7, lines 4 to 15) extra parameters are only additional to these steady state measurements.

Column 8, lines 31 to 49 again suggest taking into account further characteristics in addition to the steady state characteristics analysed previously. The only alternative suggested is to substitute any steady state power assessment by a list of potential parameters. Even the broadest aspects listed in the claims teach the necessary inclusion of the period of steady operation for this prior art analysis to be achieved.

Since 1989, U.S. Pat. No. 5,287,287 (in 1994) discloses a power consumption rate display device allowing a customer to review their power usage via an LCD panel. This device has an on-board memory so that historical data can be viewed to allow a consumer to monitor their usage over time. No discrimination of appliances is considered.

In 1996, U.S. Pat. No. 5,483,153 seems to indicate an abandonment of any clustering algorithm and an emphasis on harmonic analysis which requires a sampling rate far greater than could be expected from meters currently in use. Harmonic content analysis is achievable using existing meters but the quantity of data is large and requires significant memory and computing resources.

In 1997, U.S. Pat. No. 5,635,895 introduces a remote power cost display system. Such a system comprises two parts; the first part combining a watt meter and a transmitter to measure consumption which transmits data via the customer's electrical wiring to a second part which is a hand held display that is plugged into a power outlet connected to the wiring. It provides power consumption at that instant with no disaggregation of appliances or other analysis.

In 1998, U.S. Pat. No. 5,717,325 discloses a single point electrical monitoring and disaggregation system which uses harmonic analysis to discriminate between the start-up transients of different appliances. The disclosure implies a high sample rate. Neither clustering of events nor production of clumps are detailed.

In 2003, U.S. Pat. No. 6,553,418 discloses a system for monitoring and analysing power consumption at a variety of locations which requires numerous measuring points throughout a distribution network. It is not concerned with identifying multiple appliances by monitoring a single point. No detailed algorithm is provided.

In February 2006, U.S. Pat. No. 7,006,934 discloses a power quality detection system in an electric power meter. Sags and swells in the power supply voltage are detected and the use of harmonic analysis is envisaged. However, there is no mention of disaggregation of appliances, only a measure of overall power consumption.

In May 2006, US2006/0106741 shows a utility monitoring system that allows a consumer to monitor real time power consumption and to review previous periods of consumption data. No discrimination of appliances in terms of consumption is envisaged.

In August 2007, U.S. Pat. No. 7,252,543 discloses sub-metering methods and systems allowing landlords to sub-meter apartments in a building rather than sub-metering individual appliances. Separate sensors are required for each apartment rather than a single point measurement.

In December 2007, U.S. Pat. No. 7,304,586 discloses a metering system with the ability to collect data and wirelessly transmit the collected data to the utility operator. There is no mention of disaggregation of appliances.

Despite the numerous developments in the art since 1989, none of the previous documents suggests the improvements and their effect as presented in the following section.

### SUMMARY OF THE INVENTION

In a first broad independent aspect, the invention provides a method of inference of appliance usage from a point measurement on a supply line, said supply line being common to multiple appliances and/or components of appliances comprising the steps of:

obtaining data from said measurement point;
sampling power and reactive power at intervals substantially throughout periods of operation of said appliances or components of appliances corresponding to appliances or components of appliances being in ON and/or OFF modes of use;
identifying characteristics of events by assessing power and reactive power change during an event; and by assessing one or more additional characteristics derivable from said power and reactive power to characterise an appliance;
grouping events and/or cycles of events into clusters of characteristics; and inferring appliance usage based on said grouping.

This method is particularly advantageous because it allows appliance usage to be accurately inferred whilst lending itself to an application to meters and in particular to the resolution achieved by typical so called smart-meters. Sufficiently accurate inference of appliance usage may be obtained by sample rates of the order of every second. Therefore, the implementation of the inventive method may be carried out without significant modification to smart-meters. It also lends itself to operation for the class of energy monitor devices currently on the market. In addition, since it primarily avoids the use of harmonic analysis, the computing and mathematical resources which would otherwise be required are rendered substantially superfluous. It also avoids both the requirement of sub-metering each individual appliance and the requirements of using custom-designed meters. The installation of an apparatus running the method would be relatively straightforward. It also allows the inference of appliance usage to be achieved over time without any user interaction. It also allows real time identification and allows the identification of appliances to increase over time.

In the context of this application, the term “real time” does not necessarily mean at the same time of the unfolding event but means as soon as a switch-ON event has been isolated—typically within a few seconds of an appliance switching on. It is also particularly advantageous in terms of suitability for implementation on an embedded processor. It also employs relatively modest processing and memory resources.

In the following subsidiary aspects further improvements arise in terms of reliability of identification of an appliance.

In a subsidiary aspect, said additional characteristic is representative of the duration of an ON event.

In a further subsidiary aspect, said additional characteristic is representative of one or more transients.

In a further subsidiary aspect, said additional characteristic is representative of one or more transients associated with an ON event.

In a further subsidiary aspect, said additional characteristic is representative of a change in power associated with an ON event including a transient.

In a further subsidiary aspect, said additional characteristic is representative of a change in power associated with an ON event without a transient.

In a further subsidiary aspect, said additional characteristic is representative of a change in reactive power associated with an ON event including a transient.

In a further subsidiary aspect, said additional characteristic is representative of a change in reactive power associated with an ON event without a transient.

In a further subsidiary aspect, said additional characteristic is representative of time between an ON event and an OFF event.

In a further subsidiary aspect, said additional characteristic is representative of a change in power associated with an OFF event.

In a further subsidiary aspect, said additional characteristic is representative of a change in reactive power associated with an OFF event.

In a further subsidiary aspect, said additional characteristic is representative of the duration of a transient.

In a further subsidiary aspect, said additional characteristic is representative of a portion of the settling time of a transient.

In a further subsidiary aspect, said additional characteristic is representative of a half-settling-time of a transient.

In a further subsidiary aspect, said additional characteristic is derived from power and reactive power at the start of an event, power and reactive power at the end of said event and power and reactive power once a transient has settled.

In a further subsidiary aspect, said additional characteristic is representative of the energy associated with a transient.

In a further subsidiary aspect, said additional characteristic is a peak value during a transient.

In a further subsidiary aspect, said step for grouping events and/or cycles of events into clusters is solely based on power and reactive power and one or more characteristics derivable at a sample rate of the order of a second.

In a further subsidiary aspect, said step for grouping events into clusters is primarily based on power and reactive power and secondarily based on harmonic analysis.

In a further subsidiary aspect, the step of comparing characteristics of event and/or cycles of event corresponding to the operations of components of an appliance which occur simultaneously and/or in a similar pattern; whereby the characteristics of components of an appliance assist in the discrimination of data for the inference of the usage of an appliance.

In a further subsidiary aspect, said cluster is sub-divided into clumps.

In a further subsidiary aspect, a parameter for grouping events is the length of a clump.

In a further subsidiary aspect, the method comprises the step of comparing previously determined power, reactive power and characteristics associated with a cluster with measured power, reactive power and characteristics of an unfolding event; whereby real time identification is achieved.

In a further subsidiary aspect, the method further comprises a database of a predetermined range of cluster properties of appliances and/or their components.

In a further subsidiary aspect, the method further comprises the step of maintaining the database of cluster properties.

In a further subsidiary aspect, the method further comprises the step of tracking ON events in real time by using a buffer.

In a further subsidiary aspect, the method further comprises the step of isolating events using an edge-detection algorithm.

In a further subsidiary aspect, the method further comprises the step of assessing a power amplitude associated with an ON event under a given threshold to identify whether it is followed by a power amplitude of similar amplitude associated with an OFF event.

In a further subsidiary aspect, the method further comprises the step of assessing the regularity of events in a predetermined period.

In a further subsidiary aspect, the method further comprises the steps of setting a maximum envelope for one or more clusters, building one or more clusters for each event by including the closest event to said one or more clusters in terms of distance, selecting the next closest event until the cluster reaches said maximum envelope, recording a cluster with the most events, removing said events from said data, and repeating said preceding steps until no cluster can be found that meets the pre-defined requirement for having a minimum number of events.

In a further subsidiary aspect, in addition to and/or instead of grouping events into clusters of similar power, reactive power and additional parameters drivable from said power and said reactive power, said method incorporates the steps of predicting a pattern of power and reactive power based on an initial detected pattern of power and reactive power comparing said predicted pattern to said pattern to said detected pattern to match said usage to an appliance and/or appliance component.

In a second broad independent aspect, the invention provides a method of inference of appliance usage from a point measurement on a fluid supply line, said supply line being common to multiple appliances and/or components of appliances comprising the steps of: obtaining flow data from said measurement point; sampling flow rate to identify events corresponding to appliances or components of appliances being in ON and/or OFF modes of use; assessing flow rate to characterise an appliance; and inferring appliance usage based on said assessment.

This method may be employed for fluids such as water and/or gas to discriminate individual appliance usage. This method may in particular monitor how the amplitude of flow or the flow rate changes over time. It could also monitor patterns of change in flow rate. It could for example assess whether the changes in flow constitute cycles. The frequency of the cycles may also be assessed in order to allow an algorithm based on such a method to identify various appliances. The advantages mentioned with regard to the first broad independent aspect may to a large extent apply to the second broad independent aspect.

In a third broad independent aspect, the invention provides a method of inference of appliance usage from a point measurement on a supply line, comprising the steps of carrying out the method of the second broad independent aspect in conjunction with a method of power usage assessment.

In a subsidiary aspect, the method of inference comprises any of the steps of the power usage assessment method of any of the preceding aspects.

In a fourth broad independent aspect, the invention provides a data processing apparatus configured to operate in accordance with the method of any of the preceding aspects.

In a fifth broad independent aspect, the invention provides a computer software which configures a data processing apparatus to operate according to the method of any of the preceding aspects.

### BRIEF DESCRIPTION OF THE FIGURES

FIGS. 1A and B show hierarchical views of elements used in the analysis.

FIG. 2 shows an embodiment of an algorithm.

FIG. 3 shows an example of parameterisation for an ON event.

FIG. 4 illustrates the need to improve on hard thresholding of events.

FIG. 5 shows event matching into cycles.

FIG. 6 shows a method for retaining absolute power information within an algorithm.

FIG. 7 illustrates the probability density function representation of clusters.

FIG. 8 shows how cycles form clusters in a three dimensional space of watts, VARs and ON time.

FIG. 9 shows an example of an output of the algorithm.

FIG. 10 shows a diagram of a typical ON event.

### DETAILED DESCRIPTION OF THE FIGURES

A method of inference of appliance usage from a point measurement on a supply line is presented in detail in this section. The method may obtain data from a measurement point. The measurement point may be a single point of a supply line which supplies resources to a group of multiple appliances and/or components of appliances. The resources supplied may include electricity, water and/or gas. In the preferred embodiment described hereinafter, the resource selected is electricity.

The term “appliance” is intended to be interpreted broadly and may for example include within the scope any form of load, a resource using device, and any of the group comprising: an electric oven, a washing machine, a heating apparatus, mobile and transportable appliances, built in appliances, driers, dishwashers, fridge/freezer units, building components such as pumps and/or air conditioning units. Appliances may also include manufacturing stations and/or substations.

The supply line in a preferred embodiment is a power line. However, battery or generator powered supply lines may also advantageously incorporate an apparatus configured to operate the method of inference of appliance usage. The method may have applications in the field of domestic and commercial dwellings, whilst also being suitable for appliance usage in mobile devices such as vehicles and/or vessels.

Data is obtained from the supply line through any appropriate known metering device. The configuration of a smart meter may be adapted to tog integrated energy consumption at a higher rate than the currently selected rate of every half hour. A configuration of smart-meter to deliver a measurement at a higher rate is therefore preferred to obtain data for processing according to the method of the invention. A particularly advantageous resolution is a one second resolution since it allows even the energy monitoring devices currently on market to be employed to obtain data. The inventive method is suitable for implementation on an embedded processor.

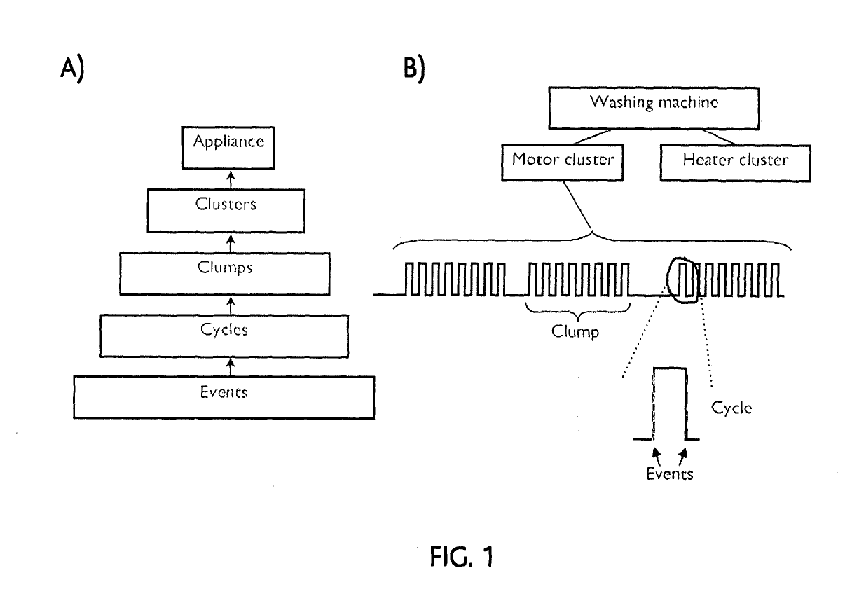

FIG. 1A shows a view of the elements used in the method. It is an example of a preferred hierarchy of elements. In this example, the first step of the analysis is to identify “events”. These are an appliance or a component of an appliance switching ON and/or OFF. ON events often have transients associated with them which may be assessed in a grouping process. The ON event detection includes a power meterisation of the transients. An ON event therefore allows the assessment of power (watts) and reactive power (VARs) at the start of the event, power (watts) and reactive power (VARs) at the end of the event and power (watts) and reactive power (VARs) once the transient has settled. Further parameters of the assessment may be the energy contained within the transient and its half-settling-time.

Events are grouped into cycles. The term “cycles” is to be interpreted broadly to include a pair of events where for example an ON event is paired to an OFF event whilst also envisaging a plurality of ON events corresponding to the same OFF event. The method incorporates steps of grouping events into one or more of the following: cycles, clumps and clusters.

A clustering algorithm is employed to group events and/or cycles together into clusters. The clustering algorithm achieves grouping according to power, reactive power and any additional parameter or characteristic derivable from the power and reactive power suitable to characterise an appliance. A preferred clustering algorithm relies on the amplitude of a cycle in watts (power), the amplitude in VARs (reactive power) and the length in time of the cycle. Further dimensions are taken into account for a particular clustering algorithm in order to further improve the discrimination of the usage in accordance with appliances and/or their components. A particular parameter or characteristic which may be taken into account is the transient. A parameter or characteristic representative of the transient may be set to be the peak power value during a transient. Another parameter or characteristic which may be taken into account is the energy contained within the transient part of an event.

The algorithm is configured to resolve the ambiguity in identifying components and/or appliances in a preferred configuration, purely resolving ambiguities from ON/OFF amplitudes of power (watts) and reactive power (VARs). The algorithm is configured and the data processing apparatus is configured to conduct the analysis without conducting the analysis of harmonic data. This reverses conventional thinking since previous non-intrusive load monitoring devices rely primarily on harmonic analysis to allow the discrimination of different appliances and/or components of appliances.

The algorithm may also be adapted to analyse clumps which are in effect components of a cluster. A cluster might, in practice, comprise many clumps which are cycles that are close together in time. A cluster that corresponds to the motor of a washing machine will contain many cycles of a few seconds' length and with certain watts and VARs which form definite clumps in time. The parameter of a length of a clump may be assessed as part of a diagnosis of an appliance.

FIG. 1B illustrates a washing machine with a motor and a heater component. In practice, the operation of the heater of the washing machine may yield data in terms of resistive load, a small transient and an ON event of a number of minutes which could be a characteristic of the heater of a dishwasher. The algorithm is configured to assess whether a heater cluster of this kind is seen during a period when the washing machine motor is on and if it is to conclude that the cluster is a washing machine water heater cluster.

The clustering approach of the algorithm is particularly effective and efficient in terms of its demands on memory and processing resources. The algorithm may be configured to result only in bulk cluster properties being stored. The algorithm may organise the storing of previously determined power, reactive power and parameters associated with a cluster and to allow the comparison of said previously stored clusters with measured power, reactive power and parameters of an unfolding event in order to provide a means for real-time identification of appliances.

Real-time identification may follow a number of steps. Once the algorithm has been assessing the data obtained from a given location for a period of a day or a few days, most appliances will have been encountered and the clusters that correspond to a particular appliance or component of an appliance—will generally be populated with a significant number of cycles. When a relatively large number of cycles have been identified, a particular cluster may be identified accurately. Once this is achieved, any new ON event will be compared with the ON characteristics of each cluster and if it has the similar/consistent/matching amplitude in watts and VARs and the same transient parameters as a cluster, then the new event is identified with that cluster and thus with the appliance that this cluster is associated with.

The algorithm is also configured to make use of a pattern of cycles in time to assign an appliance or a component of an appliance to a cluster. This further improves the accuracy of the identification.

The clustering approach is also rendered further accurate by assessing whether appliance's components are simultaneously active. For example, a cluster might be a characteristic of a dishwasher or washing machine water heater (each have similar resistive load, small transient ON for a similar number of minutes). If this particular cluster is only seen during a period when the washing machine motor is ON then it may be inferred that the cluster is a washing machine water heater.

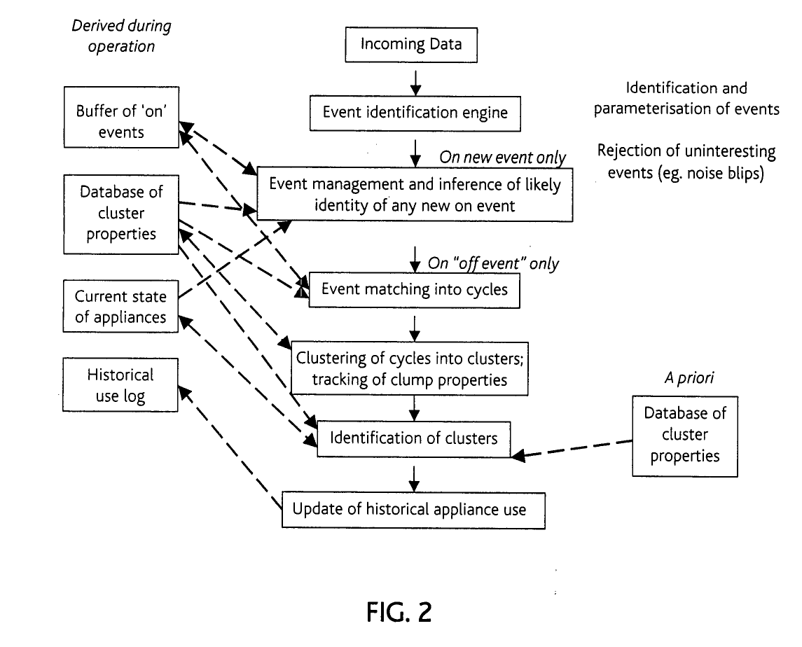

A top level flow chart is shown in FIG. 2. The algorithm makes use of a priori data in the form of look-up table that provides the range of clusters' properties that correspond to particular appliances and appliance components. The look-up table may incorporate particular ranges of amplitude in watts, ranges of amplitude in VARs and/or ranges of transient parameters; each of which are typical of a particular appliance. For example, the water heater in a washing machine may be expected to have a particular amplitude in watts lying between two values A and B when heating water. Thus, in use, the algorithm can identify a cluster which has a value in the appropriate range or ranges in order to assign it to a washing machine water heater.

The algorithm may also be configured to maintain a database of the cluster properties for a particular location. The algorithm may be configured to regularly and/or continuously add to such a database.

The algorithm is also configured to keep track of all appliances that are ON. For this purpose, a buffer of ON events is envisaged. The required buffer size may be selected to be about 10 appliances for a typical location such as a typical household.

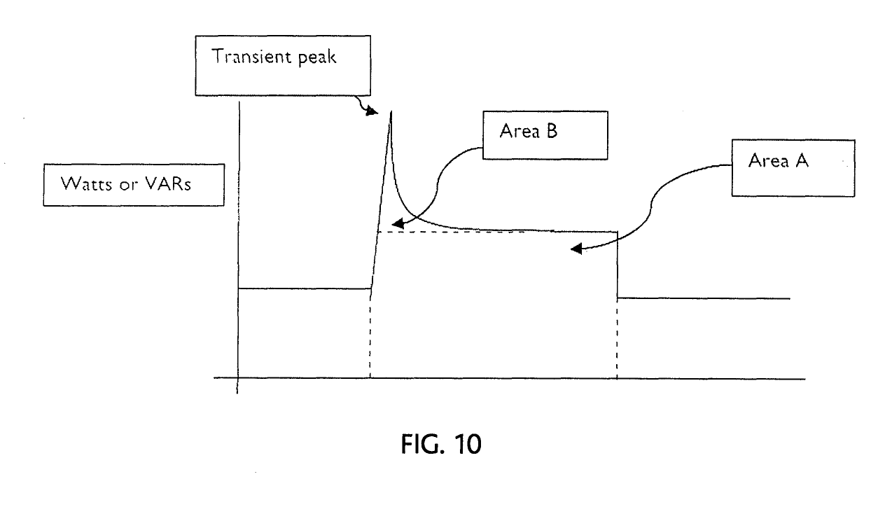

The algorithm is also configured to keep track of which appliances are currently ON in order to derive information about simultaneity of operation which is fed back into the cluster database. A historical use log is kept of which historical data is needed for display of the analysis. The data processing apparatus may incorporate means for retrieving the historical data. The historical data may be transmitted through a network for commercial analysis to be carried out remotely from the measurement point. The historical data may be communicated through a server to an end user of the appliances for assessment of their usage. A potential output of the algorithm is shown in FIG. 10.

The algorithm is configured to isolate events using an edge-detection. In a preferred embodiment, an edge-detection algorithm isolates regions where the amplitude of the gradient is continuously greater than a threshold. For example, the threshold may be set at 5 W/s in power. The algorithm is preferably configured to monitor continuous variations in power rather than simply measuring a change in steady state of power. Monitoring a change in steady state power alone would not be sufficient since a steady state is not reached before a significant period of time if many appliances are being used or if appliances which have a continuously varying load are consuming power.

The algorithm is configured to carry out edge-detection but in a preferred embodiment it does not do so alone in order to deal with transients. In addition to the edge-detection, the algorithm is configured to deal with transients by firstly establishing whether an OFF edge following an ON edge is the transient of that ON event. The algorithm is configured to assume that it is unless the amplitudes are incompatible with this being the case. Secondly, the algorithm is configured to start a transient counter which serves to monitor any settling of power following any ON event. The timer is terminated by either a subsequent significant event or by a time-out.

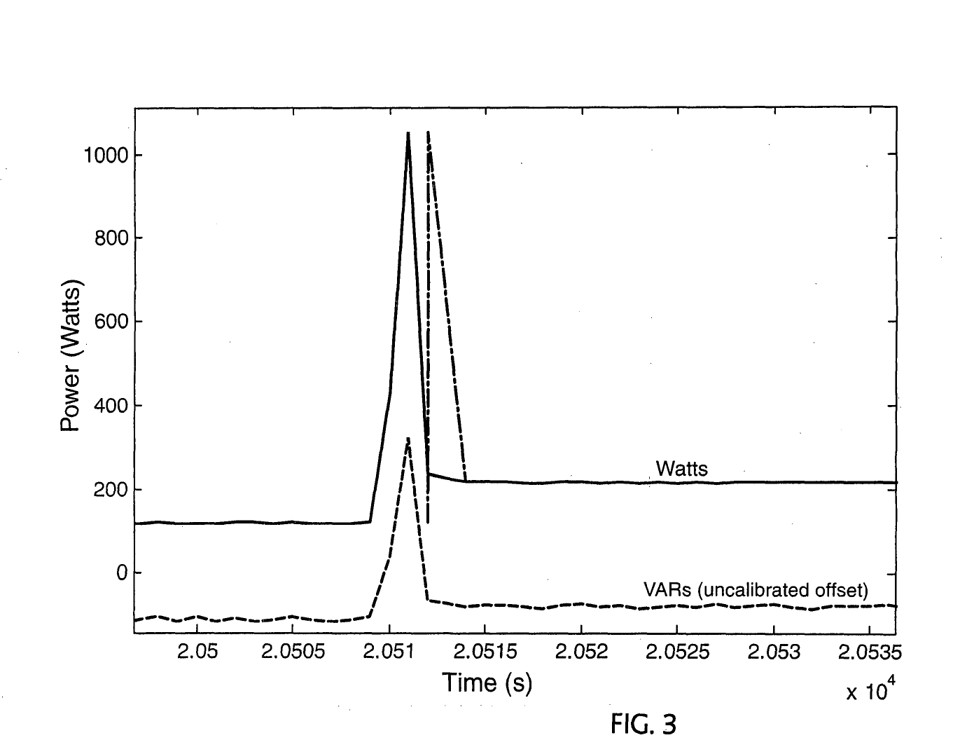

FIG. 3 shows an example of the minimum parameters required for an ON event.

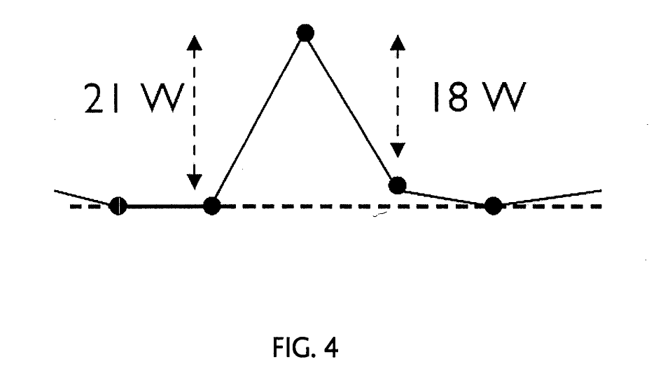

The algorithm is also configured to distinguish between real events and noise-like events. It does this by, at first, assuming that all events are real and then removing those events which are seen to be noise-like. One method to do this is to use a soft thresholding as shown in FIG. 4. In this example, any ON event which is less than 20 watts in amplitude is under probation to see if it is followed by an OFF event of similar amplitude. If so, both events are removed. If not, only the ON event is removed. Similarly, the algorithm will try to pair off an OFF event that is under the threshold in amplitude before removing it.

The algorithm is also configured to assess the current watts level to identify which events are noise-like, which improves robustness in cases where slow power drifts occur.

Each new OFF event is matched to one (or more) ON events which are then either removed or adjusted. A possible process is:

1. Is the end of the current OFF event at the same power level as the start of a previous ON event? If so, all ON events in between are subsumed into the OFF event. If not . . . .
2. Is the end of the current OFF event at the same VARs level as a previous ON event, with large and matching VARs amplitudes (this is specifically to match relatively high frequency motor events)? If so, match these events, correcting power as required where non-matching watts amplitudes indicate an overlap of cycles. If not . . . .
3. Is the OFF event a good match with a cluster (in watts and VARs) and, if so, is an ON event available in the buffer such that the resulting cycle could be added to the cluster? If not . . . .
4. Is the OFF event a good match in watts and VARs with and previous ON event?
5. Is the OFF event a good match in watts only with any previous ON event? If not . . . .
6. Is the OFF event a good match with some combination of the ON events? If not, make a note of the closest match and proceed . . . .
7. Is there a single “double switch” ON event that is consistent with the OFF event (i.e. larger than OFF)? If not . . . .
8. Take the previously identified best fit.

The invention also envisages step 6 and 7 being combined as a single step. The preceding steps may be carried out in an alternative order. A method is considered to be particularly advantageous when incorporating one or more of the preceding steps.

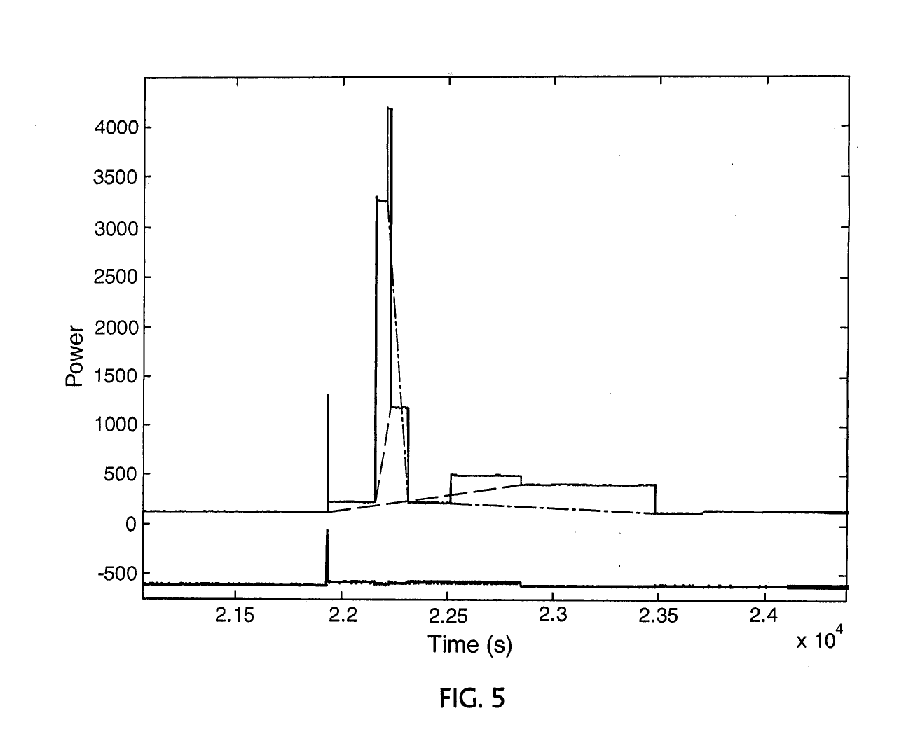

An example showing the output of the event-matching algorithm on real data is shown in FIG. 5. The dashed lines match OFF and ON events.

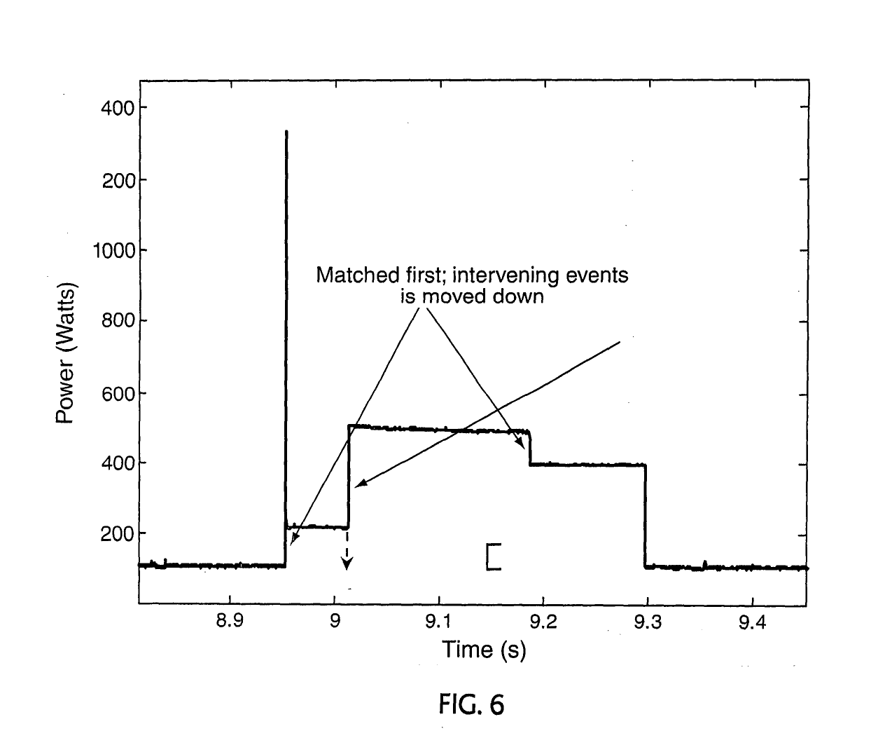

In order to achieve item 1 above, it is necessary to adjust the level of events which lie between newly matched events. As shown in FIG. 6, matched first events are identified whilst intervening events are moved down as shown by the arrow with the dashed line.

Clusters are presented as multivariate Gaussian distributions. In order to discriminate the clusters are for different appliances, three or more dimensions are employed to form a cluster. In a preferred embodiment, a 3-D space as defined by apparent power amplitude of a cycle, phase amplitude of a cycle and ON time of a cycle.

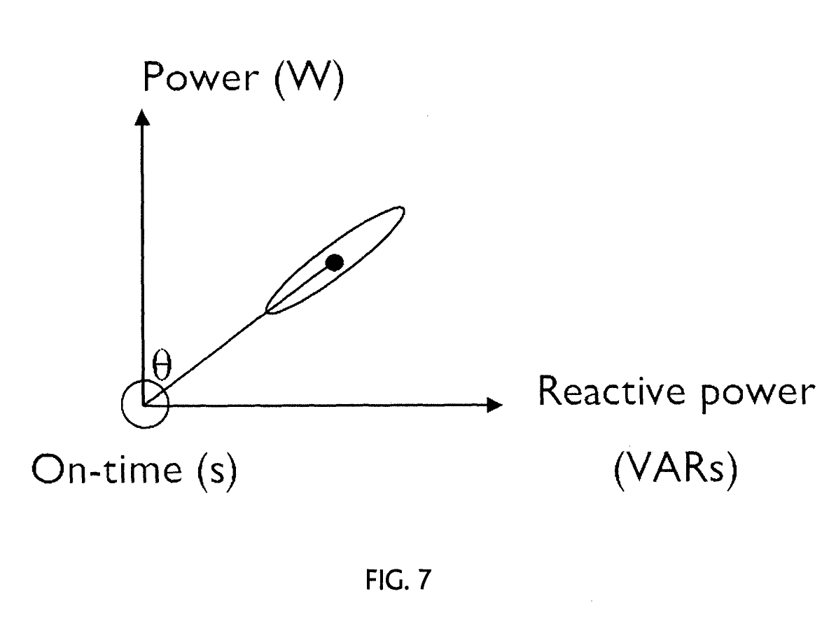

The probability density function representation of clusters is shown in FIG. 7. It is assumed that the co-variants matrix of the Gaussian distribution is diagonal in this space. When clusters are combined, a best-fit Gaussian distribution is found, using the following equations:

$$μ = \frac{{N}_{1} {μ}_{1} + {N}_{2} {μ}_{2}}{{N}_{1} + {N}_{2}}$$

$${σ}^{2} = \frac{{N}_{1} ( {σ}_{1}^{2} + {( {μ}_{1} - μ )}^{2} ) + {N}_{2} ( {σ}_{2}^{2} + {( {μ}_{2} - μ )}^{2} )}{{N}_{1} + {N}_{2}}$$

Clusters that are sufficiently overlapping (in terms of distance compared to variants) are combined.

Over time, the true statistics of a cluster are identified as the true range of cycles is encountered. Other parameters about a cluster are stored in addition to the three parameters used for clustering in this embodiment. The following parameters available about a cycle are:
Change in watts during switch ON, including transient;
Change in watts during switch ON with transient removed;
Change in VARs during switch ON including transient;
Change in VARs during switch ON with transient removed;
The time between and ON event and an OFF event;
Change in watts during switch OFF;
Change in VARs during switch OFF;
Duration of switch ON transient.

Further parameters such as for example parameters corresponding to the distribution of the cycles of a cluster may be employed for discrimination purposes. One additional parameter may for example be the mean clump length of a cluster (the mean number of cycles that appear together in a same period, for example, of 15 minutes). This further improves the diagnostic since, for example, a fridge may have a clump length of 1 (having cycles uniformly distributed over 24 hours) but a washing machine motor may have a clump length in the hundreds of cycles. Further parameterisations of the number of cycles per period such as a period of 24 hours and the regularity of cycles may also be employed.

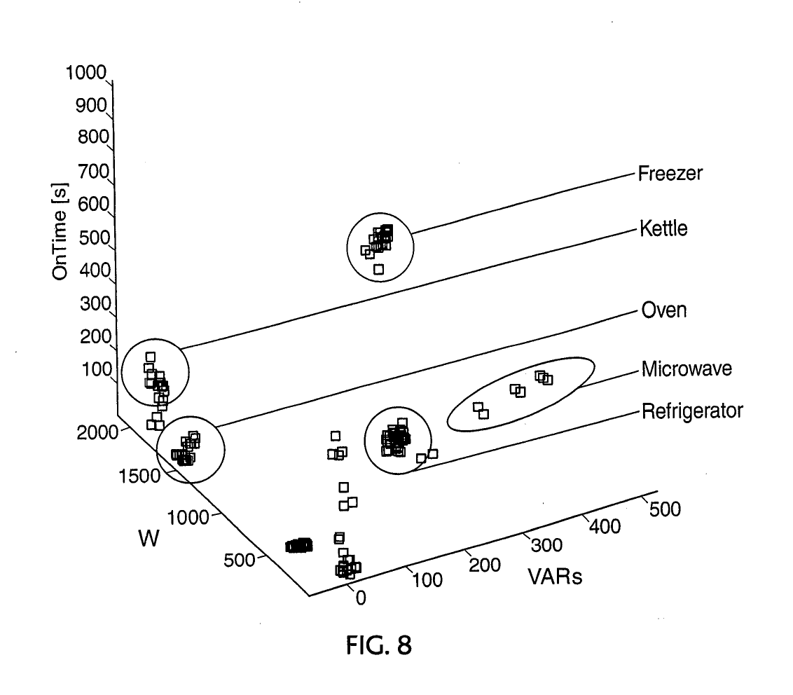

Of particular relevance is the simultaneity of clusters with components of an appliance. The fraction of time that each cluster clump is simultaneous with appliance components may also be measured. For example, the cluster that represents the start-up of an oven may look somewhat similar to a dishwasher heating cycle, but will always (as opposed to occasionally) occur just before a clump of the very characteristic oven duty-cycling cluster. The separation or discrimination of appliances into clusters is shown in FIG. 8. Clusters that occupy the same region of the three dimensional space and can still be separated into different appliances as long as they are sufficiently far apart to be in different clusters. This is achieved by employing many more parameters for appliance identification than the three used for clustering.

Appliance identification occurs constantly provided the method is configured to continuously update the properties of clusters. This continuous updating maintains an identity of a cluster. As soon as a cycle is added to a cluster, it is therefore identified. The identity of ON events can be guessed accurately from amplitude and transient properties by comparing this with the cluster information available.

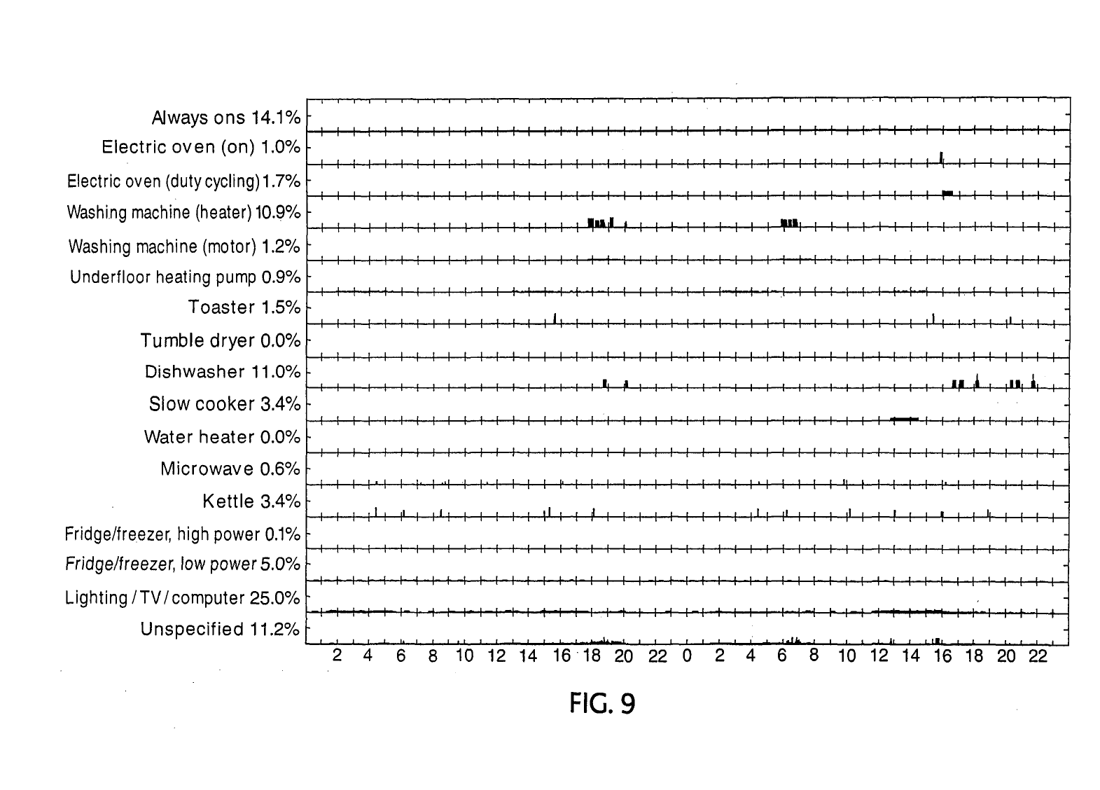

An example of typical results currently obtained is shown in FIG. 9. This technique is certainly effective in separating and correctly identifying white goods such as fridge, oven, dishwasher, washing machine, water heaters and so on. It has been shown that the performance improves as the cluster statistics, especially those relating to simultaneity are improved.

The algorithm is configured to be extendable to make best use of the data measurements available. If a meter used to obtain measurements can provide harmonic content, then the change in harmonic content (for example third harmonic components) simultaneous with an event can be used to assist in event matching and can be used as an additional dimension in the clustering algorithm.

In a preferred embodiment, the algorithm is configured to extract parameters from the raw data (watts and VARs measured at a rate of optionally 1 Hz). These additional parameters include one or more of the following:
Peak of the transient at switch ON;
Time constant of the settling time after the transient peak;
Energy contained within the transient.

The algorithm as previously detailed is configured to detect events. This additional code does not need to repeat the process, it simply takes input data beginning from the time when an event has been detected. It then locates the point immediately after the event with the largest amplitude and labels this as the peak due to the transient. After the peak the amplitude will settle to a new steady level (determined by a threshold in the gradient of the data). The algorithm is configured to fit an exponential decay to the data after the transient peak but before the new steady level is achieved and calculates a time constant that characterises this settling. The algorithm is configured to assume that the amplitude (in watts and/or VARs) is decaying according to the equation below:

Amplitude=A₀e^{-at}

Where A₀ is the amplitude at the beginning of the decay after the transient peak and a is a constant that is characteristic of the decay. By choosing two points and different times t1 and t2 in the data during this decay one can produce two simultaneous equations and then solve A₀ and a.

A(t1)=A₀e^{-at1}

A(t2)=A₀e^{-at2}

These may be employed to discriminate between events; events associated with one-off lines will have a different time constant, a, than events associated with a different appliance. Similarly, the energy contained within the transient can be obtained by calculating the area and the data up to the point when the amplitude has settled into a new steady level and then subtracting the area formed by a rectangle of height equal to the amplitude of the steady level after the ON event and with a length equal to the settling time. With reference to FIG. 10, this is equivalent to the following calculation:

Energy in transient=(Area A+Area B)−Area A

As indicated previously the energy in transient may be used as a parameter to discriminate between ON events that may appear the same when viewed in only two or three dimensions. As indicated previously the algorithm may be effective without following the specified order of processes defined in previous preferred embodiments. The method of inference of appliance usage may incorporate a member of sub-algorithms or “classifiers” used to detect specific types of appliance.

For example a fridge-classifier sub-algorithm is configured as follows:
Assume that a fridge runs continuously and thus expect there to be a continuous repeating pattern of events indicative of the fridge compressor turning off and on to maintain the temperature of the fridge.
Since the compressor will switch on at regular intervals the algorithm can predict when the next likely fridge event is going to occur, it locates events at the predicted time in the data and labels events found there as fridge events if they have amplitude and cycle durations consistent with those expected of a fridge.

Similarly, a domestic electric oven has a characteristic behaviour in which an initial long period of power usage (as the heating element increases in temperature) is followed by a series of events, increasing in frequency, which represent the heating element switching on and off as the oven's thermostat controls the temperature. A classifier similar to the one described above with reference to the fridge may be used to detect this characteristic behaviour:
If a long period of power usage at the level typical of a domestic oven's heating element is detected, followed by switching events of increasing frequency, the algorithm labels them as being associated with the oven without the need to first go through the process of event matching and clustering.

Successive applications of classifier sub-algorithms to the data results in more and more events being associated with various appliances without the need for the event matching or clustering process detailed in the previous part of this description. Once all the classifiers have operated on the data, the event matching and clustering processes outlined in the original filing can then be used to identify the remaining events or at least form them into clusters so that events can at least be assigned to an appliance even if the exact nature of that appliance (i.e. “fridge” or “kettle”) is unknown.

Problems arise when clusters begin to be separated by distances similar to the separation of the data points within the clusters as this leads to an ambiguity as to which cluster the data point belongs. By including more dimensions for each event by using extracted parameters or characteristics such as the transient peak height and time constant, it becomes easier to distinguish events that may have seemed to overlap. A sub-algorithm is configured to group event data into clusters without prior knowledge of the number of appliances. Such an algorithm may include one or more of the following steps:

A) The maximum diameter (or an envelope) is chosen for the clusters i.e. in this sense diameter is a measure of the spread of the events within the cluster.
B) A cluster is then built for each event by including the closest event to it in terms of distance in the N-dimensional space and then the next closest event and so on until the diameter of the cluster reaches the pre-set limit. The distance between events may be calculated by: d=\sqrt{a²+b²+c² . . . n²}
where d is the distance between two events and a, b and c . . . n are the difference in the values of each dimension of those events. Other measurements of distance could be made or as well as the previously defined measurement. These may include taxi-cab metering or cosine similarity. Cosine similarity calculates the scale of product of two vectors, each representing an event to produce a measure of their similarity. Two dissimilar events (orthogonal vectors) thus produce a result of zero when their scalar product is calculated.
C) Record the cluster with the greatest number of events in it and remove those events from the data.
D) Repeat steps A to C until no more clusters can be found that meet the pre-defined requirement for having a minimum number of events within them. This is particularly useful since this method of clustering will not force spurious events (“noise”) into a cluster for a particular appliance which would have a detrimental effect on the algorithm as a whole.

Clustering may be performed on events or on cycles. If the clustering is performed on events, a cluster may be obtained for the ON events for a particular appliance and a separate cluster for the OFF events. If, however the clustering is performed on cycles one cluster will be formed for each ON/OFF cycle of an appliance. It would also perform event pairing before clustering.

1-39. (canceled)

40. A method of inference of appliance usage from a point measurement on a supply line, said supply line being common to one of multiple appliances and components of appliances comprising the steps of:
obtaining data from said measurement point;
sampling power and reactive power at intervals substantially throughout periods of operation of one of said appliances and components of appliances corresponding to one of said appliances and components of appliances being in one of ON and OFF modes of use;
monitoring and assessing continuous variations in power in addition to measuring change in steady state power;
identifying characteristics of events by assessing power and reactive power change during an event; and by assessing at least one additional characteristic derivable from said power and reactive power to characterise an appliance;
grouping one of events and cycles of events into clusters of similar characteristics; and
inferring appliance usage based on said grouping.

41. A method according to claim 40, wherein said method incorporates the step of assessing change in power during switch ON including a transient.

42. A method according to claim 40, wherein said method incorporates the step of assessing change in reactive power during switch ON including a transient.

43. A method according to claim 40, wherein said additional characteristic is representative of the duration of an ON event.

44. A method according to claim 40, wherein said additional characteristic is representative of at least one transient.

45. A method according to claim 44, wherein said additional characteristic is representative of at least one transient associated with an ON event.

46. A method according to claim 40, wherein said additional characteristic is representative of a change in power associated with an ON event including a transient.

47. A method according to claim 40, wherein said additional characteristic is representative of a change in power associated with an ON event without a transient.

48. A method according to claim 40, wherein said additional characteristic is representative of a change in reactive power associated with an ON event including a transient.

49. A method according to claim 40, wherein said additional characteristic is representative of a change in reactive power associated with an ON event without a transient.

50. A method according to claim 40, wherein said additional characteristic is representative of time between an ON event and an OFF event.

51. A method according to claim 40, wherein said additional characteristic is representative of a change in power associated with an OFF event.

52. A method according to claim 40, wherein said additional characteristic is representative of a change in reactive power associated with an OFF event.

53. A method according to claim 40, wherein said additional characteristic is representative of the duration of a transient.

54. A method according to claim 40, wherein said additional characteristic is representative of a portion of the settling-time of a transient.

55. A method according to claim 40, wherein said additional characteristic is representative of a half-settling-time of a transient.

56. A method according to claim 40, wherein said additional characteristic is derived from power and reactive power at the start of an event, power and reactive power at the end of said event, and power and reactive power once a transient has settled.

57. A method according to claim 40, wherein said additional characteristic is representative of the energy associated with a transient.

58. A method according to claim 40, wherein said additional characteristic is a peak value during a transient.

59. A method according to claim 40, wherein said step for grouping one of events and cycles of events into clusters is solely based on power and reactive power and at least one characteristic derivable at a sample rate of the order of a second.

60. A method according to claim 40, wherein said step for grouping events into clusters is primarily based on power and reactive power and secondarily based on harmonic analysis.

61. A method according to claim 40, comprising the step of comparing characteristics of one of event and cycles of event corresponding to the operations of components of an appliance which occur simultaneously or in a similar pattern; whereby the characteristics of components of an appliance assist in the discrimination of data for the inference of the usage of an appliance.

62. A method according to claim 40, wherein said clusters is sub-divided into clumps.

63. A method according to claim 40, wherein a parameter for grouping events is the length of a clump.

64. A method according to claim 40, further comprising the step of comparing previously determined power, reactive power and characteristics associated with a cluster with measured power, reactive power and characteristics of an unfolding event; whereby real time identification is achieved.

65. A method according to claim 40, further comprising a database of a predetermined range of cluster properties of one of appliances and their components.

66. A method according to claim 40, further comprising the step of maintaining a database of cluster properties.

67. A method according to claim 40, further comprising the step of tracking ON events in real time by using a buffer.

68. A method according to claim 40, further comprising the step of isolating events using an edge-detection algorithm.

69. A method according to claim 40, further comprising the step of assessing a power amplitude associated with an ON event under a given threshold to identify whether it is followed by a power amplitude of similar amplitude associated with an OFF event.

70. A method according to claim 40, further comprising the step of assessing the regularity of events in a predetermined period.

71. A method according to claim 40, further comprising the steps of setting a maximum envelope for at least one cluster, building at least one cluster for each event by including the closest event to said at least one cluster in terms of distance, selecting the next closest event until the cluster reaches said maximum envelope, recording a cluster with the most events, removing said events from said data, and repeating said preceding steps until no cluster can be found that meets the pre-defined requirement for having a minimum number of events.

72. A method according to claim 40, wherein in addition to or instead of grouping events into clusters of similar power, reactive power and said additional parameters derivable from said power and said reactive power, said method incorporates the steps of predicting a pattern of power and reactive power based on an initial detected pattern of power and reactive power and comparing said predicted pattern to said detected pattern to match said usage to one of an appliance and an appliance component.

73. A method of inference of appliance usage from a point measurement on a fluid supply line, said supply line being common to one of multiple appliances and components of appliances comprising the steps of:
obtaining flow data from said measurement point;
sampling flow rate to identify events corresponding to one of appliances and components of appliances being in one of ON and OFF modes of use;
assessing flow rate to characterise an appliance; and
inferring appliance usage based on said assessment;
wherein the method further comprises the steps of carrying out a power usage assessment according to the method of claim 40.

74. Data processing apparatus configured to operate in accordance with the method of claim 40.

75. Computer software which configures a data processing apparatus to operate according to the method of claim 40.
